(19) United States
(12) Patent Application Publication
(10) Pub. No.: US 2003/0209191 A1
(43) Pub. Date: Nov. 13, 2003

(54) Ammonothermal process for bulk synthesis and growth of cubic GaN

(76) Inventor: Andrew P. Purdy, Alexandria, VA (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/142,800

(22) Filed: May 13, 2002

(51) Int. Cl. C30B 23/00; C30B 25/00; C30B 28/12; C30B 28/14

(52) U.S. Cl. 117/84

(57) ABSTRACT

A method of growing single-crystals of a cubic (zinc blende) form of gallium nitride, the method comprising the steps of:

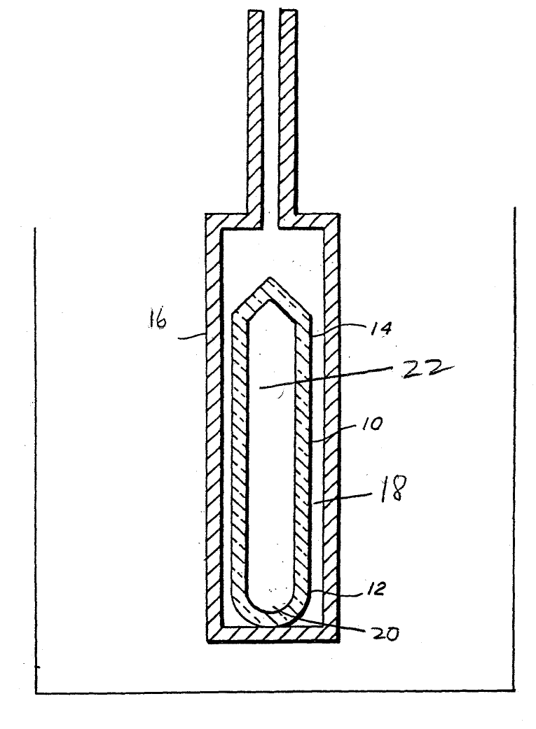

placing into a reaction tube or acid resistant vessel a gallium source, anhydrous ammonia, an acid mineralizer and a metal halide salt selected from the group consisting of alkali metal halides, copper halides, tin halides, lanthanide halides and combinations thereof;

closing said reaction tube or vessel;

heating said reaction tube;

cooling said reaction tube or vessel; and

collecting single-crystals of cubic (zinc blende) form of GaN;

wherein said reaction tube or vessel has a temperature gradient with a hot zone of at least 250° C.,

wherein said reaction tube or vessel has a temperature gradient with a cool zone of at least 150° C., and

wherein said acid mineralizer has a sufficient concentration to permit chemical transport of GaN in said reaction tube or vessel from said hot zone to said cool zone due to said temperature gradient within said reaction tube or vessel.

### BACKGROUND OF THE INVENTION

1. Field of the Invention

The present invention relates to a method of growing cubic (zinc-blende) GaN crystals, and more particularly, to a method of growing single trigonal prisms of cubic (zinc blende) GaN as a substrate for epitaxial growth for use in semiconductor devices.

2. Background Art

Gallium III nitride has been considered a desirable material for use in semiconductor devices. The metastable cubic (zinc-blende) form of GaN has been grown heteroepitaxially on lattice-matched substrates, e.g., β-Sic, GaAs or MgO, see Niewa et al., “Recent Developments in Nitride Chemistry”, Chem. Mater., 1998, 10, 2733; Neumayer et al., “Growth of Group III Nitrides, A Review of Precursors and Techniques”, J. G. Chem. Mater., 1996, 8, 9; Monemar, “III-V nitrides-important future electronic materials”, J. Mat. Sci. Mater. Electron, 1999, 10, 227; and Ambacher, “Growth and Applications of Group III Nitrides”, J. Phys. D: Appl Phys., 1998, 31, 2653. The bulk synthesis of cubic GaN was described in U.S. Pat. No. 6,177,057 to Purdy, and in Purdy, “Ammonothermal Synthesis of Cubic Gallium Nitride”, Chem Mater., 11, 1648-1651, 1999, which are incorporated herein by reference. The ammonothermal method described in Purdy grew both hexagonal, h-GaN, and cubic, c-GaN, crystals. The single-crystals of GaN were 1-30 micrometers in length. Ammonothermal growth with alkaline mineralizers, e.g., alkali amides, seems to transport and thus grow only the hexagonal phase. The length of the h-GaN was 0.5 mm, “Crystal Growth of Gallium Nitride in Supercritical Ammonia”, Ketchum, D. R. et al., J. Cryst. Growth, 2001, 222, 431-434. Ammonothermal growth with acidic mineralizers is apparently a very complicated process as the product mix (c-GaN v h-GaN), product yield, crystal size and crystal morphology is each extremely sensitive to reaction conditions. To date, none of the disclosed methods of preparation of zinc-blende c-GaN have afforded high quality large single-crystals of zinc-blende c-GaN for use as substrates in semiconductors. Some triangular prisms of c-GaN have been grown, but those crystals have either been very small (much less than 100 μm in length) or highly pitted, etched, segmented, or otherwise of very low quality.

### OBJECTS AND BRIEF SUMMARY OF THE INVENTION

Accordingly, an object of this invention is a method of growing single-crystals of zinc-blende c-GaN by adding a co-mineralizer.

Another object of this invention is method of growing single-crystals of c-GaN in triangular prisms having (−1 1 −1), (1 −1 1), (0 1 1), (−1 −1 0), and (1 0 −1) faces.

A further object of this invention is a method of growing single c-GaN crystals that can be seen with a naked eye (e.g., of about 1 mm in length).

A yet another object of this invention is method of reacting and/or dissolving a gallium source, e.g., gallium III or gallium III compound, in an acid mineralizer, a metal halide salt (co-mineralizer) and anhydrous ammonia and growing single-crystals of zinc-blende c-GaN in triangular prisms for use as a seed in growing larger crystals of zinc-blende c-GaN using the same disclosed method.

A yet still another object of this invention is to be able to transport the GaN from a hot spot in the reaction tube to a cool spot in the reaction tube, i.e., in a temperature gradient, for attachment and crystal growth on a surface in the cold zone.

A still further object of this invention is to provide a co-mineralizer to aid in depositing the c-GaN crystals.

Another object of the invention is a method of growing high quality, large single-crystals of zinc-blende triangular prisms of cubic GaN having (−1 1 −1), (1 −1 1), (0 1 1), (−1 −1 0), and (1 0 −1) faces as a substrate for epitaxial growth and for use in semiconductor device.

These and other objects of this invention can be attained by possibly reacting and/or dissolving a gallium source, e.g., gallium metal or gallium compounds, with an acid mineralizer, anhydrous ammonia and a metal halide salt at super critical conditions.

### SUMMARY OF THE INVENTION

These and other objects of this invention are achieved in a preferred method of the invention by a method of growing single-crystals of a cubic (zinc-blende) form of gallium nitride, the method comprising the steps of:

placing into a reaction tube or acid resistant vessel a gallium source, anhydrous ammonia, an acid mineralizer and a metal halide salt selected from the group consisting of alkali metal halides, copper halides, tin halides, lanthanide halides and combinations thereof;

closing said reaction tube or vessel;

heating said reaction tube;

cooling said reaction tube or vessel; and

collecting single-crystals of cubic (zinc blende) form of GaN;

wherein said reaction tube or vessel has a temperature gradient with a hot zone of at least 250° C.,

wherein said reaction tube or vessel has a temperature gradient with a cool zone of at least 150° C., and

wherein said acid mineralizer has a sufficient concentration to permit chemical transport of GaN in said reaction tube or vessel from said hot zone to said cool zone due to said temperature gradient within said reaction tube or vessel.

Another embodiment of the present invention is a method of growing single-crystals of zinc-blende c-GaN, the method comprising the steps of:

placing into a sealable container a gallium source, anhydrous ammonia, an acid mineralizer and a co-mineralizer to a fill factor level of from about 25-75%;

sealing said container;

heating a hot zone of said container to of from about 470 to about 520° C. for a sufficient period of time; and

solubilizing, transporting and growing single-crystals of zinc-blend c-GaN until all said gallium source is dissolved; and

wherein said container has a hot zone and a cool zone due to a temperature gradient within said container, and

wherein said hot zone is positioned within an area occupied by contents of said container.

A further embodiment of the invention is a method of manufacturing a substrate wafer of c-GaN for use in a semiconductor device, the method comprising the steps of:

placing into a container a gallium source, anhydrous ammonia, an acid mineralizer and a co-mineralizer to a fill factor of from about 25-80%;

sealing said container;

heating said container,

solubilizing, transporting and growing triangular prisms of zinc-blende c-GaN until all said gallium source is dissolved;

cooling said container;

collecting a seed of a triangular prism of c-GaN; and

placing said seed of a triangular prism of c-GaN in a cool zone of a container; and

repeating said steps of placing a gallium source, anhydrous ammonia, an acid mineralizer and a co-mineralizer in a container, sealing, heating, solubilizing, transporting, growing and placing a larger seed of a triangular prism of c-GaN in a container until a sufficiently large triangular prism of c-GaN is grown; and

cutting the said triangular prism of c-GaN into wafers.

wherein said containers have a hot zone and a cool zone due to a temperature gradient within said containers.

Another embodiment of the present invention is a method of growing single-crystals of a cubic (zinc blende) form of gallium nitride, the method comprising the steps of:

placing into a reaction tube or acid resistant vessel a gallium source, anhydrous ammonia, NH₄Cl, _{and} LiCl;

closing said reaction tube or vessel;

heating said reaction tube;

cooling said reaction tube or vessel; and

collecting single-crystals of cubic (zinc blende) form of GaN;

wherein said reaction tube or vessel has a temperature gradient with a hot zone of at least 250° C.,

wherein said reaction tube or vessel has a temperature gradient with a cool zone of at least 150° C., and

wherein said acid mineralizer has a sufficient concentration to permit chemical transport of GaN in said reaction tube or vessel from said hot zone to said cool zone due to said temperature gradient within said reaction tube or vessel.

### BRIEF DESCRIPTION OF THE INVENTION

These and other objects, features and advantages of the invention, as well as the invention itself, will become better understood by reference to the following detailed description when considered in connection with the accompanying drawing wherein like reference numerals designate identical or corresponding parts throughout the several views, and wherein:

The FIGURE is a schematic illustration of a system containing a sealed reaction tube counter pressured with a fluid.

### DETAILED DESCRIPTION OF THE INVENTION

Referring now to the drawing, the method for growing a triangular prism of zinc-blende c-GaN for use as a seed crystal in growing a larger triangular prism of c-GaN for use as a substrate.

Generally, the bulk synthesis of single-crystals of triangular prisms of c-GaN involves an ammonothermal synthesis process, in which a solvent, anhydrous ammonia; an acid mineralizer; co-mineralizer; and a gallium source are placed in reaction tube having a temperature gradient therein. The contents of the reaction tube are heated to the supercritical temperature of the solvent and triangular prisms of c-GaN are formed in the cool zone of the reaction tube.

The apparatus that is schematically illustrated in the FIGURE can be used to carry out the process described herein. The apparatus as shown in the FIGURE where 10 is the reaction tube or a quartz tube with a bottom 12 and a top 14. Reaction tube 10 is disposed vertically and generally centrally within steel pressure vessel 16. Between the tube 10 and pressure vessel 16 is a fluid 18, e.g., water. The apparatus is also known as Leco HR-1-2 hydrothermal system and is commercially available. The hot zone, near the bottom of the steel pressure vessel 16 is indicated at 20 and cool zone is indicated at 22 in the reaction tube.

Initially the contents are placed into the reaction tube 10, which is then heated to a temperature above 150° C. There is a temperature gradient within the reaction tube. The hot zone in the reaction tube has a temperature of from 275-600° C. due to the heat furnace, not shown, either pre-heated or heated to a temperature 30-70° C. above the desired hot zone temperature. When hexagonal GaN is used as the feedstock the desired hot zone temperature is typically 450-520° C. The temperature gradient in this apparatus appears to be in −10° C. increments every cm up the reaction tube away from the hot zone 20. The location of the cool zone 22 where deposition occurs varies depending on halide ion, fill, and other parameters but typically begins at around 10 cm from the hot zone 20 for a 16-17 cm reaction tube and extends for 3-7 cm for a temperature range of about 100-200° C. below the hot zone temperature. Crystals are grown from the cool zone to the top of the vertically positioned reaction tube due to the solvothermal transport from the hot zone to the cool zone. All temperatures are measured after about 3 hours of heating.

The reaction tube 10 is usually a quartz glass tube, which is sealed by application of a torch flame at the opposite end from where the contents are placed. If the reaction tube 10 is not made of glass, valve closure or the like can be used to seal the tube contents from the atmosphere. As an acid mineralizer is one of the compositions placed into the reaction tube, an acid resistant vessel can also be used. If the reaction tube is made of or contains quartz, an ammonium fluoride acid mineralizer is not used since it can dissolve quartz. Furthermore, if ammonium fluoride were used as the acidic mineralizer, intermediate formation of gallium fluoride could be problematic since gallium fluoride is insoluble in ammonia. Alternatives to using a quartz reaction tube include using a reactor fabricated from corrosion resistant alloys and directly pressurized with the ammonia, or a metal reactor lined with a corrosion resistant material, e.g., platinum, molybdenum, quartz, Teflon, or ceramic.

In the reaction tube 10, is placed liquid anhydrous ammonia and other solid compositions. The reaction tube 10 is sealed and the ammonia is heated above its supercritical temperature. Concomitantly, as the tube 10 is being heated the vapor pressure of the ammonia is rapidly increasing to at least 500 psi, typically 10,000-60,000 psi. High pressure is typically used for the solvothermal transport of the desired product by one of the added compositions from the hot zone.

The high pressure can burst the reaction tube 10 unless pressure is provided to the outside of the reaction tube. Explosion of the reaction tube can be overcome by placing the reaction tube in a pressure vessel 16 and introducing water, argon, CO₂, NH₃ or another fluid 18, into the pressure vessel 16 around the reaction tube. Water is then pressurized to provide a counter-pressure around the reaction tube when the pressure vessel is placed in a furnace and the contents in the reaction tube are heated. Typically, the counter-pressure is sufficient to prevent explosion of the reaction tube. The initial counter-pressure at room temperature is provided by pressurizing water to a pressure on the order of 5,000-10,000 psi. Counter-pressure that is too high can result in implosion of the reaction tube. The initial counter-pressure is highly dependent on the size of the reaction tube, the volume of the pressure vessel (autoclave) in which the reaction tube is heated and the geometry or configuration to whatever system it is attached.

Each reaction tube 10 has a fill factor based on the volume of free space in the reaction tube above the level of the contents in a solvent at room temperature. Sufficient ammonia is used to obtain a fill factor in the reaction tube, typically 25-95%, more particularly, 30-85%, and desirably of from about 50-70%. Fill factors below 20% do not produce product because there is an insufficient amount of ammonia in the reaction tube to act as the solvent. Fill factors above 95% provide excessive pressure thereby resulting in an explosion when the tube is heated above the supercritical temperature of the solvent. The fill factor establishes the pressure in the reaction tube after it is sealed and heated. The product will not be formed if an excessive or insufficient fill factor occurs.

Into the reaction tube is placed anhydrous ammonia, an acid mineralizer, a metal halide salt and a gallium source, e.g., gallium and/or a gallium compound(s). “A” can mean one or more. Either chunk or particulate gallium metal can be used. In the event that a gallium compound is to be used, it is desirable to have the surface of a gallium compound impurity free so as to increase its dissolution in the solvents. Both h-GaN and c-GaN can be used in their respective crystalline forms. High quality h-GaN is synthesized in large quantities through the chemical vapor reaction process, CVRP, alkali metal flux, AMF, and many other known processes. Platelets of millimeter size h-GaN can be prepared in bulk by a reaction of Ga with NH₄X vapors in a tube furnace (CVRP), and by reaction of Ga with N₂ at 750° C. in a Na, or Na/K alloy flux (AMF). Many commercially available GaN powders are contaminated with oxides or fluorides or are otherwise too impure to be used as the feedstock. CVRP and AMF produce GaN that can be used as the feedstock.

Anhydrous ammonia, the nitriding solvent, is condensed into the reaction tube, e.g., at −196° C. The anhydrous ammonia can be purchased from Air Products or many other sources and it can be used as received or be subject to an additional drying step for higher purity. Hydrazine or a mixture of ammonia and hydrazine can also be used for the solubilizing of the gallium source. The ammonia is placed into the reaction tube as a liquid. Sufficient ammonia is placed into the reaction tube so as to have the desired fill factor.

An acid mineralizer is any substance that is soluble in the ammonia solvent and produces H+ or NH₄+ ion. The acid mineralizer reacts and/or dissolves with the gallium source in order to solubilize the gallium source in the ammonia solvent and acts as a transport in the formation of the crystals. The acid mineralizer is typically used in the form of a solid powder but it can also be used in a liquid form.

Acid mineralizers include ammonium halides, NH₄X, where X is —Br, —Cl and —I. The ammonium halide salts are soluble in ammonia and do not react with ammonia. X can also be any negative ion, such as azide, that does not react with ammonia or any other substance found in the mixture. Most ammonium salts are soluble in ammonia due to the formation of hydrogen bonds between the salt and ammonia. Other suitable acid mineralizers are hydrazinium halides.

At a temperature between 300° and 550° C., solvothermal transport occurs under the ammonoacidic conditions. Solvothermal transport involves solubilization of the material in the lower or the hotter zone and recrystallization of crystalline gallium nitride on the inner surface of the reaction tube in the upper or the cooler zone. The temperature can be quickly raised to the level where growth occurs and is maintained at that temperature for an extended period of time while crystals slowly grow. Alternatively, a 2-step heating procedure can be used, for instance when converting Ga metal to GaN at a temperature too low to cause transport, typically from 250-350° C., and then raising the temperature to transport and recrystallize the gallium nitride. The acid mineralizer is required to react and/or dissolve GaN. If too much of the acid mineralizer were used there would be no GaN crystal growth. A simple explanation for this result is that dissolution of the GaN produces some gallium halide species, equation 1, and the deposition involves ammonolysis and condensation of the halides to GaN and NH₄X. The soluble species is presumably some molecule or cluster containing both halide and nitrogen containing ligands. The gallium-halogen bonds will undergo ammonolysis or in other words react with ammonia in the cool zone to regenerate the ammonium halide and add a nitrogen containing ligand to the Ga. The presence of too much NH₄X in solution will inhibit an ammonolysis, equation 2, by LeChatelier×s Principle. Likewise, an excessive NH₃ fill factor will inhibit the condensation reaction, equation 3, by the same LeChatelier's principle.

(hot zone)(GaN)ₙ+zNH₄X GaᵥN_{w}(NH)ₓ(NH₂)_{y}X_{z} 1

(cool zone)>Ga-X+2NH₃→>Ga-NH₂+NH₄X(ammonolysis) 2

(cool zone)2>Ga—NH₂>Ga—NH—Ga<+NH₃(condensation) 3

X=Cl, Br, I; w+x1.5+(y+z)/3=v; v>=1

The precise identities of the solution species are unknown, but the possibilities are almost unlimited. Everything from trihalides to halide-imides, halide-amides, nitride clusters, and both neutral and anionic species may be present. A reasonable speculation is that different intermediates are responsible for the deposition of either the hexagonal or cubic phases of GaN.

The amount of the acid mineralizer is typically from a trace amount to 10.0 moles per mole of the gallium source, gallium and/or gallium compound(s), however, the amount may vary outside those ranges depending on the feedstock used and the scale of the reaction. When h-GaN is used as the feedstock, a particular concentration of acid mineralizer in the ammonia solution may be utilized regardless of the amount of feedstock present. The effectiveness of a particular mineralizer will depend to some extent on the temperature, fill factor and co-mineralizer used. A small amount of acid mineralizer can mean a long reaction time before the product is obtained, and can dramatically lower the yield of the cubic GaN for some reactions. However, low molar levels of acid mineralizer can produce less contamination of the products and thus improve the quality, particularly, for the recrystallization of pre-made GaN. Using higher molar levels of a gallium source, gallium and/or gallium compound(s), and an acid mineralizer can increase the growth rate of the product crystal materials. Slower growth rates should allow the formation of a better quality crystal. However, the dynamics are very complicated, and the relationship between the rate of transport and the concentration of a given NH₄X mineralizer, with all other conditions being equal, is highly nonlinear (bromides) with at least one maximum in the transport rate, see Examples 12 and 13 (bromides) and Examples 3 and 16 (chlorides). When the starting feedstock is a compound, such as Gal₃ that reacts with ammonia to form an ammonium halide, no mineralizer need be added as the mineralizer is formed in situ by the reaction of the feedstock with ammonia, and the amount of acid mineralizer is determined by the amount of feedstock added.

It is known to the hydrothermal art, but not in the nitride area, that the addition of additives or co-mineralizers to a solvothermal reaction system can affect the transport and growth of the material being crystallized. Such additives can complex or otherwise modify the chemical species in solution, increase or decrease the dissolution of the feedstock, affect the rate at which crystals are deposited, suppress or enhance particular reaction pathways, complex or chemically bind to surfaces of materials being grown or dissolved, or otherwise affect the crystal growth process in both desirable or undesirable ways. Complexation or binding can preferentially occur on a particular face or surface of a growing crystal and thus induce the formation of a particular crystalline phase or a particular crystal habit. Solvothermal processes are typically very complicated, and the effect of a particular additive on a particular system can usually only be determined by trial and error. There were many co-mineralizers tried that did not provide the desired product. Typically, a co-mineralizer will not by itself facilitate transport, but will modify the chemical transport and crystal growth process. However, some co-mineralizers, such as SnX₄ (X=Cl, Br, and I) will react with ammonia to produce NH₄X in situ and thus serve as both the co-mineralizer and the source of the ammonium halide mineralizer. In numerous reactions, addition of lithium halides increased the proportion of the crystals deposited in the growth zone that were composed of the cubic form of gallium nitride, when starting from a wide variety of feedstocks. Furthermore, with particular mineralizers and feedstocks, the addition of lithium halide causes crystals of c-GaN to grow larger, more regular, more reliably, or otherwise have higher quality than crystals grown without the addition of lithium halide. The optimum amount of LiX can vary widely depending on conditions, but is typically added in a concentration at least 10% of, and often in large excess (700% or more) over that of the acid mineralizer, see Examples 3, 4, and 7. Salts of Cu(I) and Sn also show desirable effects. For instance, when starting from GaI₃ as feedstock, the GaN growth often, but not always, contains significant proportions of the hexagonal form in addition to the cubic form, and usually contains large portions of irregular and dendritic growth. Addition of LiI or CuI, with all other conditions being equal, reproducibly results in a deposit that is pure c-GaN, and is composed of highly regular triangular prisms. The amount of LiI or CuI added can be from about 10% to 1000% the molar amount of Gal₃. When LiBr is used as a co-mineralizer with NH₄Br and an h-GaN feedstock, the rate of feedstock dissolution and transport at least doubles. Utilization of LiCl co-mineralizer with NH₄Cl allows the growth of nice, transparent, regular triangular prisms of c-GaN, which do not grow under the same conditions when the LiCl is not present. The lithium cation has approximately the same size as the Ga³⁺ cation and might complex or bind to the same sites as a gallium ion, but other ions of similar size have little or no effect and the actual mechanism of action is unknown. It is possible that the Li ion is incorporated into the GaN product, as the color of the product produced with an additive will usually be different than the product without the additive. GaN deposits produced with NH₄Cl mineralizer are typically light green in color. When LiCl is present, the typical color of the triangular prisms of c-GaN is a deep yellow. C-GaN deposits produced using NH₄I mineralizer are usually orange. The presence of LiI typically results in a lighter shade of orange or a yellow color and CuI usually results in a deeper orange color. Salts of Cu(I) and Sn also show desirable effects. For instance, when starting from Gal₃ as feedstock, the GaN growth often, but not always, contains significant proportions of the hexagonal form in addition to the cubic form, and usually contains large portions of irregular and dendritic growth. Addition of LiI or CuI, with all other conditions being equal, reproducibly results in a deposit that is pure c-GaN, and is composed of highly regular triangular prisms. The amount of LiI or CuI added can be from about 10% to 1000% the molar amount of Gal₃.

Once the appropriate amounts of ammonia, acid mineralizer, gallium source and co-mineralizer have been placed in the reaction tube to the appropriate fill factor, the reaction tube is sealed. The reaction tube is placed vertically in a pressure vessel, autoclave, and a furnace is positioned around the bottom, lower end, of the reaction tube.

The heating of the reaction tube should be of a sufficient duration for the crystal growth of c-GaN. Typically, longer growth times afford larger crystals until the point is reached where all the feedstock has transported. Growth in the hotter portions of the growth zone may also dissolve slowly with time and deposit in the coolest part, or onto the seed crystals suspended in the growth zone. The duration is less than a year, typically up to 1 month, more typically between 1/2-400 hours, and most typically between several days and several weeks. A solvothermal process is occurring during the heating step when the temperature in the reaction tube is at the supercritical temperature or above of the solvent, e.g., ammonia. Thus, during the heating step, the crystals of c-GaN are deposited at the middle to upper portion, cool zone, of the reaction tube based on the vertical positioning of the reaction tube and the temperature gradient within the reaction tube. The reactor tube may also be positioned horizontally, or in some other configuration, and may be equipped internally with baffles, screens, or other obstructions to control the flow patterns and/or enforce a particular thermal gradient, as is typical in the art of hydrothermal or solvothermal crystal growth.

The temperature gradient between the top and the bottom of the reaction tube while the reaction tube is vertically positioned within the pressure vessel, autoclave, and the furnace is about 100-200° C., but can be substantially higher or lower. The temperature difference should be sufficient to form c-GaN in the reaction tube and at a minimum 10° C. For a given set of starting conditions of feedstock, mineralizer, co-mineralizer, fill, and hot-zone temperature, there will be a minimum and a maximum temperature where crystal growth of c-GaN will occur, and there will be a narrow zone within that temperature range, typically at the cooler end, where the best crystals will grow. The FIGURE indicates a hot zone 20 in a lower position and a cool zone 22 in a higher or upper position while the reaction tube is in a vertical position. When the reaction tube 10 is in a horizontal position, a temperature gradient is still found, i.e., there are a hot zone and a cool zone. The temperature gradient should be at least 0.01° C. per cm to 100° C. per cm, typically 5-15° C./cm of the reaction tube length for a laboratory scale apparatus. These conditions can be found when the laboratory method is scaled up.

Following the heating step is a cooling step. The reaction tube is cooled to room temperature over a period of hours, typically as quick as possible for a given apparatus in order to prevent the deposition of unwanted low quality crystals at a temperature lower than the optimum growth temperature for a given feedstock-mineralizer-co-mineralizer-fill combination. Once the reaction tube is sufficiently cooled, the reaction tube is opened and crystals are removed. In the event the reaction tube is placed in a pressure vessel, autoclave, which was heated to the fluid's supercritical temperature to provide the counter-pressure, the pressure vessel is cooled prior to removal of the reaction tube.

In the examples, all handling of solid reactants and Na/K alloy was done in a Vacuum-Atmospheres dri-lab. The anhydrous NH₃ (Air Products) was used as received. The Li salts and CuI were heated under vacuum at >300° C. to dry, and the ammonium halides were vacuum sublimed before use. All potentially hydroscopic solids were stored in the dri-lab. X-ray powder diffraction patterns were obtained with a Phillips diffractometer with a graphite monochromator using Cu Koc radiation. SEM photographs were recorded on a LEO 1550 electron microscope and an Intel QX3 microscope was used for optical photographs. The fractions of the GaN deposits consisting of the cubic and hexagonal phases was determined from the intensities of their X-ray powder diffraction lines. The procedure disclosed in MRS Internet J. Nitride Semicond. Res, 1999, 4, 1 by Callahan, M. et al., “Synthesis and Growth of Gallium Nitride by the Chemical Vapor Reaction Process (CVRP)” was used to synthesize CVRP-GaN feedstock.

### EXAMPLE 1

Ammonothermal Reactions in Quartz Tubes, General Procedure:

Anhydrous ammonia was condensed at −196° C. into a 17-20 cm long, 5 mm OD, and 3 mm ID or an 8 mm OD, 4 mm ID quartz tube containing the reactants and the tube was flame sealed at height (interior measure) of about 13-17 cm. The exterior of the tube was pressurized with water inside an MRA-114R or MRA-138R pressure vessel attached to a Leco HR-1B hydrothermal system to about 10,000 or 5,000 psi, respectively, and the pressure vessel was heated in a vertical orientation resulting in a pressure of 30,000-40,000 psi at equilibrium temperature. All reaction temperatures were measured in the thermowell near the bottom of the pressure vessel, hot zone. The formula for estimating the temperature in a 5 mm OD quartz tube as a function of thermowell temperature and vertical position is est temp+Thermowell temp−(24+10×height (cm))° C. based on earlier studies and the formula est temp=Thermowell temp−(14+9.8×height (cm))° C. was determined for the 8 mm OD tubes in a similar manner. After temperature program was completed, the tubes were allowed to cool at a natural rate (up to 2 hours) to at least 200° C. before lowering the furnace, and to room temperature before removal of the reaction tube from the pressure vessel. All tubes were frozen at −196° C. before opening, and the products were washed with dilute HCl to remove Ga halides and any oxides/hydroxides formed from exposure of Ga halides to air. The acid wash was followed by EtOH and acetone washes and air-drying of the GaN.

### EXAMPLE 2

Synthesis of h-GaN in Na/K Flux:

A Na/K alloy was prepared from equal weights of Na and K. In the dri-lab, a 30 ml alumina crucible with lid was loaded with 10 g of Na/K and 5 g Ga and placed into an Aminco Superpressure vessel with internal dimensions of 1.5 in dia.×10.5 in long (volume of 305 cm³), a copper gasket seal, and a cold rating of 14,000 psi. The vessel was pressurized with high purity N₂ to 1500 psi, and the lower half of the vessel was heated in a furnace under N₂ atmosphere (to prevent oxidation) in a vertical orientation to 775-800° C. for 183 hours. The furnace assembly was located in a box constructed of 1/8 in steel plate to protect against catastrophic failure. After returning to room temperature, the excess NaK was poured out and the remaining Na/K was neutralized with ethanol in a dry box purged by flowing nitrogen. The product was soaked in conc. HCl for several hours to remove intermetallics and then washed with H₂O and alcohol and dried. The crust on the surface had h-GaN prisms, and the bulk material consisted of h-GaN platelets; 3.0g isolated.

### EXAMPLE 3

A 4 mmID/8 mm OD quartz tube which was sealed at one end was charged with 110.7 mg of hex-GaN, (hexagonal GaN was synthesized by the alkali metal flux process) 30 mg LiCl, and 5.5 mg NH₄Cl. Anhydrous NH₃ (36.1 mmol) was condensed into the tube on a vacuum line, and the tube was flame sealed at an interior height of 16.3 cm. The pressure vessel was then heated in a 550° C. tube furnace in a vertical orientation for 42 h such that the hot zone of the pressure vessel was at 477° C. After returning to room temperature, the tube was frozen with liquid nitrogen, opened, and the GaN deposit (102.7 mg) at the top was removed. The very top of the dark yellow deposit consisted of triangular prisms of c-GaN with flat, regular faces. The crystals were up to 100 um across the triangular face and up to 200 um long.

### EXAMPLE 4

The reaction of Example 3 was repeated with 450 mg of feedstock and a run time of 92 h. 210 mg of GaN, which contained many yellow, transparent triangular prisms of c-GaN deposited near the top of the tube.

### EXAMPLE 5

Single-Crystal Analysis of c-GaN Crystals from Examples 3 and 4:

The cell constants for the 4.512(5) Å cubic cell were determined on a Bruker 1K CCD from 78 reflections using Mo-Ka radiation at −180° C. The yellow translucent crystal from Example 3 was a 0.16 (long)×0.02×0.02 mm tapered triangular prism, 0.02 mm at the base, and 0.005 mm at the tip. The base and tip of the crystal have faces of (1−11) and (−11−1), respectively. The three sides of prism are nominally the (011), the (−1−10), and the (10−1) faces. A second (larger) crystal from Example 4 was examined by single-crystal X-ray analysis and was determined to have the same cell and exhibited the same growth habit.

### EXAMPLE 6

An 8 mmOD/4 mmID tube was charged with 99 mg of GaN synthesized by the CVRP process, 4.9 mg NH₄Cl, and 36.1 mmol of NH₃. The tube was sealed at a height of 16.3 cm and heated for 92 h with a hot zone temp of 480° C. Most of the feedstock remained at the bottom of the tube and only 9.4 mg of a GaN deposit grew. There were no large crystals in the deposit.

### EXAMPLE 7

A 8 mm ID/4 mmOD quartz tube was charged with 450 mg of the same CVRP-produced GaN used in Example 6, 5 mg NH₄Cl, 30 mg LiCl, and 36.1 mmol NH₃. The tube was sealed at a height of 16.5 cm and the hot zone heated to a temperature of 471° C. for 10 days. All the GaN feedstock dissolved, and 425 mg of deposit was produced. The yellow, transparent triangular prisms in the upper portion of the deposit were up to 0.05 mm in width and 0.8 mm in length.

### EXAMPLE 8

Gallium metal (49 mg), NH₄Cl (50 mg), and LiCi (40 mg) were sealed with NH₃ (25.0 mmol) in a 3 mm ID/5 mmOD quartz tube with an interior length of 16.9 cm. The tube was heated in the usual manner by inserting the autoclave into a furnace pre-heated to 550° C.; the hot zone of the vessel was 497° C. After 17 h, dark yellow clusters of triangular prisms of c-GaN deposited on the interior quartz wall between 10.9 and 12.8 cm from the bottom of the tube.

### EXAMPLE 9

Gallium Triiodide (370 mg) and CuI (100 mg) were sealed with 36.1 mmol NH₃ in a 4 mm ID/8 mm OD quartz tube with an interior height of 16.7 cm, and heated for 3 days in the usual manner. Hot-zone temp was 495° C. After cool-down, an orange deposit of pure c-GaN (58.8 mg, 85% yield) was isolated from the top of the tube. SEM photographs showed the deposit to consist of triangular prisms of c-GaN, 3-5 um wide across the triangular face and 20-30 um long.

### EXAMPLE 10

Gallium Triiodide (370 mg) and LiI (100 mg) were sealed with 36.1 mmol NH₃ in a 4 mm ID/8 mm OD quartz tube with an interior height of 16.3 cm, and heated for 3 days in the usual manner. Hot-zone temp was 508° C. After cool-down, an orange deposit of pure c-GaN (63.4 mg, 92% yield) was isolated from the top of the tube. SEM photographs showed the deposit to consist of triangular prisms of c-GaN, of up to 50 um long and 5-10 um wide.

### EXAMPLE 11

GaN (112 mg) and NH₄Br (8.5 mg) were sealed with 36.1 mmol NH₃ in an 8 mmOD/4 mmID quartz tube with an interior length of 16.5 cm, and heated at 488° C. (hot zone) for 42 h in the usual manner. A 56 mg GaN deposit was 80% c-GaN and 20% h-GaN.

### EXAMPLE 12

An 8 mmOD/4 mmID quartz tube was charged with GaN (300 mg), 62 mg NH₄Br, 62 mg LiBr, and 36.1 mmol NH₃. The tube was sealed at an interior height of 16.3 cm and heated to 486° C. for 62 h in the usual manner. The dark yellow GaN deposit (152 mg) was 95% cubic phase, and consisted mostly of triangular needles about 10 um (w)×25 um (1).

### EXAMPLE 13

GaN (110 mg), NH₄Br (8.5 mg), and LiBr (47 mg) were sealed with 36.1 mmol NH₃ in an 8 mmOD/4 mmID quartz tube with an interior length of 16.2 cm, and heated at 492° C. (hot zone) for 42 h in the usual manner. A 108 mg deposit of pure c-GaN was isolated from the top of the tube.

### EXAMPLE 14

Gallium metal (20 mg) and SnBr₄ (32 mg) was sealed with 12.5 mmol NH₃ in a 5 mmOD/3 mmID tube such that the fill factor was 37%. The tube was heated in the usual manner with the hot zone temperature of 456° C. for 17 h. The deposits in the middle to top of the tube consisted of light yellow clusters of triangular needles of c-GaN and balls of Sn metal.

### EXAMPLE 15

Hexagonal GaN (205 mg) was sealed in a 5 mm OD/3 mm ID quartz tube with 210 mg NH₄I, 210 mg LiI and 16.3 mmol NH₃ at a 65% fill factor and heated to a hot-zone temperature of 480° C. in the usual manner. No GaN transported.

### EXAMPLE 16

A reaction in a 5 mmOD/3 mmID tube starting with 105 mg h-GaN, 50 mg NH₄Cl, 50 mg LiCl, and 25 mmol NH₃ at a fill factor of 66% deposited 37 mg GaN when the hot zone was maintained at 520° C. for 17 h. The deposit consisted of globular formations of small (0.005 mm) c-GaN cones.

### EXAMPLE 17

Gal₃ (50 mg) and NdI₃ (58 mg) were combined in a 5 mm OD/3 mmID tube with 20 mmol NH₃ at a 62% fill factor and heated at a hot zone temperature of 485° C. in the usual manner for 17 h. A light yellow deposit of pure c-GaN, weighing 5.3 mg, grew.

Hexagonal GaN was sealed in a 5 mm OD/3 mmID quartz tube with NH₃ and NH₄X, where X is Cl, Br or I, and heated in a temperature gradient to get transport and growth of GaN from the hot zone to the cool zone portions of the reaction tube. A total end-to-end gradient of 140-180° C. was estimated. The h-GaN was dissolved from a hot zone temperature between 480-520° C. and GaN deposited in a cooler zone that estimated to start at 385-420° C. and end at 350-390° C. in the 5 mm OD tubes for all three halide ions. In the 8 mm OD tubes, the start temperature of the growth zone was more correlated to the halide ion and increased in the order Cl<Br<I from 335 to 345/365 to 385° C., respectively, and the growth continued to the tops of the tubes in most cases. Most of the GaN deposits were composed primarily of the cubic phase as determined by X-ray powder diffraction, but some hexagonal phase was almost always present. With all other factors being equal the presence of LiX as a co-mineralizer increased the proportion of cubic phase in the deposited GaN, compare Example 11 to 13. The rate at which GaN is chemically transported to the top of the tubes was not linear with NH₄X concentration, but instead appeared to have at least one maximum, as with no acid mineralizer there was no transport, with intermediate amounts there was appreciable transport (Examples 3, 4, 7, and 11-13), and excessive acid mineralizer (Example 15) again resulted in no transport. The presence of LiCl or LiBr also appeared to increase the transport rate, at least at low acid mineralizer concentrations (compare Example 6 to 7 and 11 to 13).

When GaI₃ was used alone as the Ga source, the fraction of the deposit that was c-GaN varied irreproducibly from about 90% to 100% cubic GaN (Purdy A. P., Chem. Mater, 1999, 11, 1648). However, when LiI or CuI were added under similar conditions (Examples 9 and 10) a deposit of pure c-GaN grew, and that deposit consisted mostly of small triangular prisms. These examples were repeated several times and gave consistent and repeatable results. The addition of a lanthanide halide co-mineralizer (NdI₃) to Gal₃ (Example 17) also reproducibly promoted the deposit of the cubic phase. In the latter case, the c-GaN deposit consisted of small triangular platelets and was light yellow in color.

The morphology of the deposits, as shown by SEM micrographs, is dependent on conditions. Several growth patterns occur in the GaN deposits at the top of the tube. One is a uniform nucleation on the quartz tube wall with needles growing perpendicular to the wall, a pattern that is apparent in at least some of the deposits produced in most of the examples. Usually, the needles become thicker or wider as they grow affording cones, wedges, or tapered triangular prisms. Wedge-shaped growths of c-GaN were observed before under a wide variety of conditions (Purdy, A. P., Chem. Mater., 1999, 11, 1648; and Jegier et al., Chem. Mater. 2000, 12, 1003). Small clusters of needles growing from a point were obtained in a few cases (for instance Example 14), and globular formations were also deposited, as in Examples 8 and 16. Clusters of rods or needles were previously observed in ammonoalkaline crystal growth of h-GaN, and also in other systems, e.g., the ammonothermal growth of AlN. (Dwilinski et. al., Acta. Physica Polonica A, 1996, 90, 763; and Peters, J. Cryst. Growth, 1990, 104, 411)

Many of the reactions with LiX co-mineralizers produced triangular prisms of c-GaN that exceeded 10 micrometers in all dimensions. The largest crystals were grown using NH₄Cl acid mineralizer at a concentration of 0.28 mol % and LiCl co-mineralizer at a concentration of 2.0 mol %. The width across the triangular faces varied from 0.01 mm to over 0.1 mm, probably due to variations in temperature and surface nucleation within and between the experiments. Length was clearly related to growth time, and the longest single crystal c-GaN needles were obtained in the example that had the longest growth time (Example 7). In the later example, the crystals at the very top of the tube, i.e., the coolest zone, were substantially larger than those below. The presence of larger crystals at the top of the growth zone is a typical pattern that was apparent in most of the examples. Also, the deposits of large triangular prisms at the top 5 mm of Example 3 consisted of only c-GaN, while the total deposit contained some tiny crystals of h-GaN. The latter was also a typical pattern for all the examples with NH₄Cl mineralizer and LiCl co-mineralizer that lends support to the idea that h-GaN and c-GaN crystals grow from different chemical intermediates that preferentially deposit at different temperatures. As most of the stray seeds are hexagonal when h-GaN is used as the feedstock, at least initially, these results show the growth of c-GaN to be driven by the chemistry of the system. Also, there did not seem to be an appreciable difference in behavior between CVRP-GaN and AMF-GaN as a nutrient.

Sometimes growth of needles would terminate and wider triangular prisms would grow on top of the layer of thinner ones, possibly due to geometric constraints or from an excessive growth rate. Single-crystal X-ray diffraction experiments (Example 5) show that these triangular needles grew in a (1-11) direction. A full single-crystal structure of c-GaN has been reported previously (Yamane et. al., “Zinc-Blende-Type Cubic GaN Single Crystals Prepared in a Potassium Flux”, Jpn. J. Appl. Phys., 2000, 39, L146). The triangular prisms are tapered, with the taper increasing in width along the direction of growth, and growth appeared to be stepwise rather than smooth with both regions of high taper and regions of more uniform cross section. As the crystals produced to date are nearly large enough to be tied to fine wires for use as seeds, these growth patterns suggest that doing a similar reaction on a much larger scale for a long growth time would provide crystals large enough to isolate and use in seeded growth. Growth of much larger single-crystals will require the suspension of single-crystal seeds in the growth cool zone with a carefully controlled temperature.

There were some acid mineralizers that did not appear to work. They were: some transition and alkaline earth metals salts, e.g., Mn, Ni, Co, Mg, Zn, and Be. Heavier alkali metal chlorides and bromides were not sufficiently soluble. The heavier alkali metal iodides seemed to have little effect.

Therefore, what has been described above is a method, which utilizes a co-mineralizer, an acid mineralizer, a gallium source and anhydrous ammonia, for fabricating a triangular prism c-GaN for use as a substrate in semiconductor devices.

It should therefore readily be understood that many modifications and variations of the present invention are possible within the purview of the claimed invention.

What is claimed is:

1. A method of growing single-crystals of a cubic (zinc blende) form of gallium nitride, the method comprising the steps of:
placing into a reaction tube or acid resistant vessel a gallium source, anhydrous ammonia, an acid mineralizer and a metal halide salt selected from the group consisting of alkali metal halides, copper halides, tin halides, lanthanide halides and combinations thereof;
closing said reaction tube or vessel;
heating said reaction tube;
cooling said reaction tube or vessel; and
collecting single-crystals of cubic (zinc blende) form of GaN;
wherein said reaction tube or vessel has a temperature gradient with a hot zone of at least 250° C.,
wherein said reaction tube or vessel has a temperature gradient with a cool zone of at least 150° C., and
wherein said acid mineralizer has a sufficient concentration to permit chemical transport of GaN in said reaction tube or vessel from said hot zone to said cool zone due to said temperature gradient within said reaction tube or vessel.

2. The method according to claim 1, further including the step of:
placing said sealed reaction tube or vessel in a pressure reactor to be externally pressurized by a fluid selected from the group consisting of water, CO₂, NH₃, argon and other fluids; and
wherein said reaction tube is made of quartz, glass or material incapable of withstanding high internal pressure.

3. The method according to claim 1, wherein said acid mineralizer is an ammonium halide.

4. The method according to claim 3, wherein said ammonium halide is selected from the group consisting of is NH₄C₁, NH₄Br, NH₄I and combinations thereof

5. The method according to claim 1, wherein the metal halide salt is selected from the group consisting of LiI, LiBr, LiCl, CuI, CuBr, CuCl, SnCl₄, SnBr₄, SnI₄ and combinations thereof.

6. The method according to claim 1, wherein said acid mineralizer is formed in situ by a reaction of said gallium source or said metal halide salt and said anhydrous ammonia; and wherein said gallium source is a gallium halide.

7. The method according to claim 6, wherein said gallium halide is GaI₃, and wherein said metal halide salt is Lil₃, and wherein said acid mineralizer formed in situ is NH₄I.

8. The method according to claim 1, wherein said hot zone in said reaction vessel is of from about 450 to about 550° C., and wherein said cool zone is of from about 350 to about 410° C.

9. The method according to claim 1, wherein said gallium source is selected from the group consisting of h-GaN, c-GaN, Ga, GaI₃ and mixtures thereof.

10. The method according to claim 1, wherein said reaction tube is heated to a temperature to convert said gallium source to gallium nitride.

11. The method according to claim 1, wherein the c-GaN is a triangular prism.

12. The method according to claim 11, wherein said triangular prism of c-GaN has (1−11), (−11−1), (011), (−1−10), and (10−1) faces.

13. The product of the process of claim 1.

14. The method according to claim 13, further including the steps of:
placing said product in a cool zone of a reaction tube or acid resistant vessel;
charging said reaction tube or vessel with a gallium source, anhydrous ammonia, an acid mineralizer and a metal halide salt selected from the group consisting of alkali metal halides, copper halides, tin halides, lanthanide halides and combinations thereof;
sealing said container;
heating said container;
cooling said container; and
growing a larger crystal than said product of cubic (zinc blende) form of GaN grown in said cool zone of said tube or vessel.

15. A method of growing single-crystals of zinc-blende c-GaN, the method comprising the steps of:
placing into a sealable container a gallium source, anhydrous ammonia, an acid mineralizer and a co-mineralizer to a fill factor level of from about 25-75%;
sealing said container;
heating a hot zone of said container to of from about 470 to about 520° C. for a sufficient period of time; and
solubilizing, transporting and growing single-crystals of zinc-blend c-GaN until all said gallium source is dissolved; and
wherein said container has a hot zone and a cool zone due to a temperature gradient within said container, and
wherein said hot zone is positioned within an area occupied by contents of said container.

16. The method according to claim 15 wherein said c-GaN is triangular prisms.

17. The method according to claim 16, wherein said triangular prisms have a width of at least 0.1 mm and a length of at least 1 mm.

18. The method according to claim 17, wherein triangular prism faces are (1−11), (−11−1), (011), (−1−10), and (10−1).

19. The method according to claim 15, wherein said fill factor is of from about 65%.

20. The method according to claim 15, wherein said acid mineralizer is selected from the group consisting of ammonium chloride, ammonium iodide, ammonium bromide and combinations thereof.

21. The method according to claim 15, wherein said co-mineralizer is selected from the group consisting of lithium halides, copper halides, tin halides, lanthanide halides and combinations thereof.

22. The method according to claim 21, wherein said gallium source is h-GaN.

23. The method according to claim 15, wherein said acid mineralizer is formed in situ by a reaction of said gallium source and said anhydrous ammonia.

24. The product of claim 15.

25. A substrate for use in a semiconductor device comprising:
a wafer cut from a triangular prism zinc-blende c-GaN crystal.

26. The substrate according to claim 25, further including at least one epitaxial layer grown on said c-GaN layer.

27. A method of manufacturing a substrate wafer of c-GaN for use in a semiconductor device, the method comprising the steps of:
placing into a container a gallium source, anhydrous ammonia, an acid mineralizer and a co-mineralizer to a fill factor of from about 25-80%;
sealing said container;
heating said container,
solubilizing, transporting and growing triangular prisms of zinc-blende c-GaN until all said gallium source is dissolved;
cooling said container;
collecting a seed of a triangular prism of c-GaN; and
placing said seed of a triangular prism of c-GaN in a cool zone of a container; and
repeating said steps of placing a gallium source, anhydrous ammonia, an acid mineralizer and a co-mineralizer in a container, sealing, heating, solubilizing, transporting, growing and placing a larger seed of a triangular prism of c-GaN in a container until a sufficiently large triangular prism of c-GaN is grown; and
cutting the said triangular prism of c-GaN into wafers.
wherein said containers have a hot zone and a cool zone due to a temperature gradient within said containers.

28. The method according to claim 27, wherein said gallium source is h-GaN and said acid mineralizer source is selected from the group consisting of ammonium chloride, ammonium bromide, ammonium iodide and combinations thereof.

29. The method according to claim 27, wherein said co-mineralizer is selected from the group consisting of lithium halide, copper halide, tin halide, lanthanide halides and combinations thereof.

30. The method according to claim 27, wherein a concentration ratio of acid mineralizer to co-mineralizer is of from about 1:1 to about 1:10.

31. The method according to claim 27, further including the step of:
epitaxially growing a layer on said c-GaN substrate wafer.

32. A method of growing single-crystals of a cubic (zinc blende) form of gallium nitride, the method comprising the steps of:
placing into a reaction tube or acid resistant vessel a gallium source, anhydrous ammonia, NH₄Cl, and LiCl;
closing said reaction tube or vessel; heating said reaction tube;
cooling said reaction tube or vessel; and
collecting single-crystals of cubic (zinc blende) form of GaN;
wherein said reaction tube or vessel has a temperature gradient with a hot zone of at least 250° C.,
wherein said reaction tube or vessel has a temperature gradient with a cool zone of at least 150° C., and
wherein said acid mineralizer has a sufficient concentration to permit chemical transport of GaN in said reaction tube or vessel from said hot zone to said cool zone due to said temperature gradient within said reaction tube or vessel.
